(19) United States
(12) Patent Application Publication
(10) Pub. No.: US 2010/0027217 A1
(43) Pub. Date: Feb. 4, 2010

(54) PORTABLE COMPUTER WITH IMPROVED HEAT DISSIPATION

(75) Inventor: CHAO-JEN CHEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/324,857

(22) Filed: Nov. 27, 2008

(30) Foreign Application Priority Data
Jul. 31, 2008 (CN) 200810303267.2

(51) Int. Cl. H05K 5/02

(52) U.S. Cl. 361/679.55; 312/223.2

(57) ABSTRACT

A portable computer includes a base and a supporting member. The base defines a receiving portion. The supporting member includes a hinge member and a support leg. The supporting member is pivotally coupled to the base via the hinge. The support leg is capable of rotating around the hinge member from a first position to a second position. The support leg is received in the receiving portion when the support leg is positioned at the first position. The support leg is configured for supporting the base when the support leg is positioned at the second position.

### BACKGROUND

1. Field of the Invention

Embodiments of the present disclosure relate to portable computers and, particularly, to a portable computer with improved heat dissipation.

2. Description of the Related Art

Portable computers, such as laptop computers and note-book computers, have become increasingly popular for general use. These portable computers are also becoming smaller and more powerful. As the size decreases and the power of the computer increases, more heat is generated from the computer and cooling of the computer becomes a challenge. One technique for cooling a portable computer is the use of a heat-dissipating pad that is placed under the portable computer.

However, the pad must be carried with the computer all the time and thus is inconvenient. If the portable computer is used without the pad, the portable computer may overheat and malfunction.

Accordingly, it is desirable to provide a portable computer with improved heat dissipation.

### BRIEF DESCRIPTION OF THE DRAWINGS

FIG. 1 is a schematic isometric view of a portable computer having a supporting member according to a first embodiment.

FIG. 2 is a cross-sectional view taken along line II-II of FIG. 1, showing the supporting member in a first position.

FIG. 3 is a cross-sectional view taken along line II-II of FIG. 1, showing the supporting member in a second position.

FIG. 4 is a cross-sectional view of the portable computer according to a second embodiment.

FIG. 5 is a cross-sectional view of the portable computer according to a third embodiment.

### DETAILED DESCRIPTION OF THE EMBODIMENTS

Embodiments of the disclosure will now be described in detail with references to the accompanying drawings.

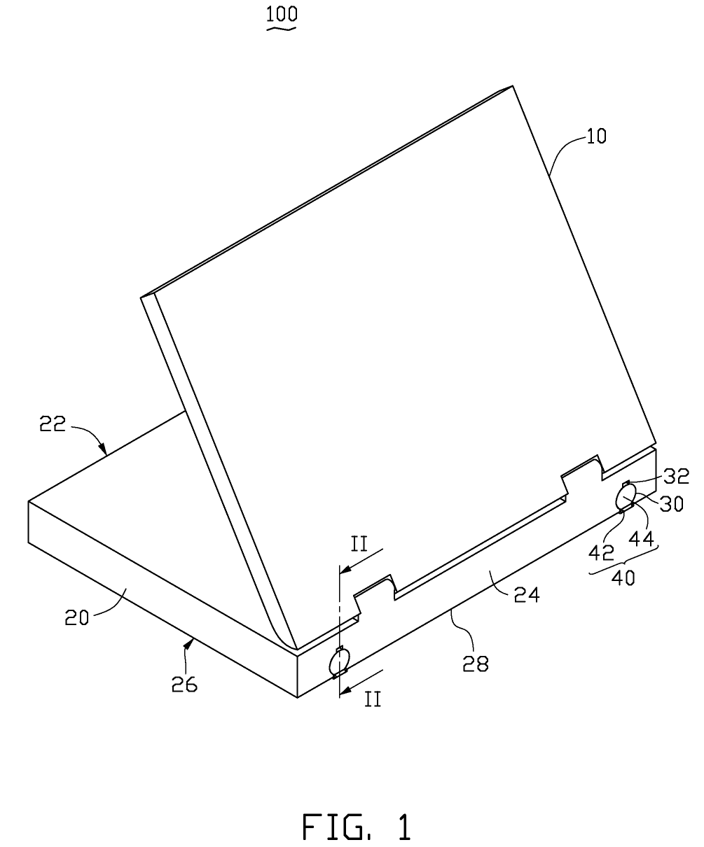

Referring to FIGS. 1-3, a portable computer 100 according to a first embodiment includes a cover 10, a base 20, and a supporting member 40. The cover 10 is pivotally connected to the rear portion of the base 20. The supporting member 40 is configured for supporting the base 20.

The base 20 includes a front surface 22, a rear surface 24, two parallel side surfaces 26, and a bottom surface 28. The front surface 22 is parallel to the rear surface 24. The front surface 22, the rear surface 24, and the side surfaces 26 are connected to the bottom surface 28. The rear surface 24 is pivotally connected to the rear portion of the cover 10. A receiving portion 30 is defined in the base 20. The receiving portion 30 can be defined on the front surface 22, the rear surface 24, or the side surfaces 26. In this embodiment, the two receiving portions 30 are defined in the rear surface 24 of the base 20. Each the receiving portion 30 is a circular recess.

The supporting member 40 includes a hinge member 42 and a support leg 44. The support leg 44 is pivotally coupled to the base 20 via the hinge member 42. The hinge member 42 is disposed at the junction 24a of the rear surface 24 and the bottom surface 28. In the embodiment, the hinge member 42 is a pin. The support leg 44 can be hemispherical, cubical, or rectangular. In the embodiment, the support leg 44 is hemispherical. The support leg 44 has a spherical surface 44a and a base surface 44b.

The support leg 44 is capable of rotating around the hinge member 42 from a first position to a second position. If the portable computer 100 is not in use, the support leg 44 is positioned at the first position, that is, the support leg 44 is received in the receiving portion 30 and the spherical surface 44a is in the receiving portion 30.

If the portable computer 100 is required to dissipate heat, the support leg 44 is positioned at the second position, that is, the base surface 44b is in contact with the bottom surface 28 of the base 20 for supporting the base 20.

In the embodiment, two supporting members 40 are disposed on opposite ends of the rear surface 24 of the base 20 correspondingly. Moreover, it is to be noted that although two supporting members 40 are exemplarily illustrated herein, one or more than two supporting members 40 may be optionally adopted in the present portable computer by those skilled in the art and be within the scope thereof. For example, four supporting members 40 and receiving portions 30 may be symmetrically disposed on the two side surfaces 26 of the base 20.

To allow the support leg 44 to be easily pulled out of the receiving portion 30, a gap 32 is defined on the edge of the receiving portion 30.

To firmly hold the support leg 44 in the receiving portion 30 or when in contact with the bottom surface 28 of the base 20, securing members are disposed on the portable computer 100. In the embodiment, the portable computer 100 includes a first securing member 82, a second securing member 84 and a third securing member 86. The first securing member 82 is mounted on the support leg 44. The second and third securing member 84, 86 are respectively mounted in the receiving portion 30 and the bottom surface 28 of the base 20.

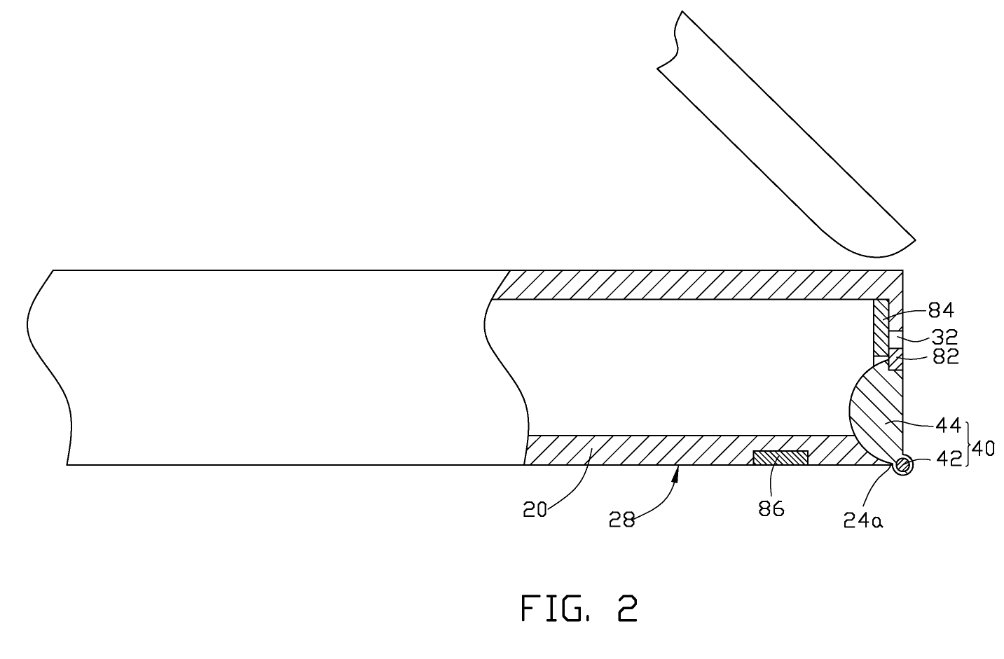

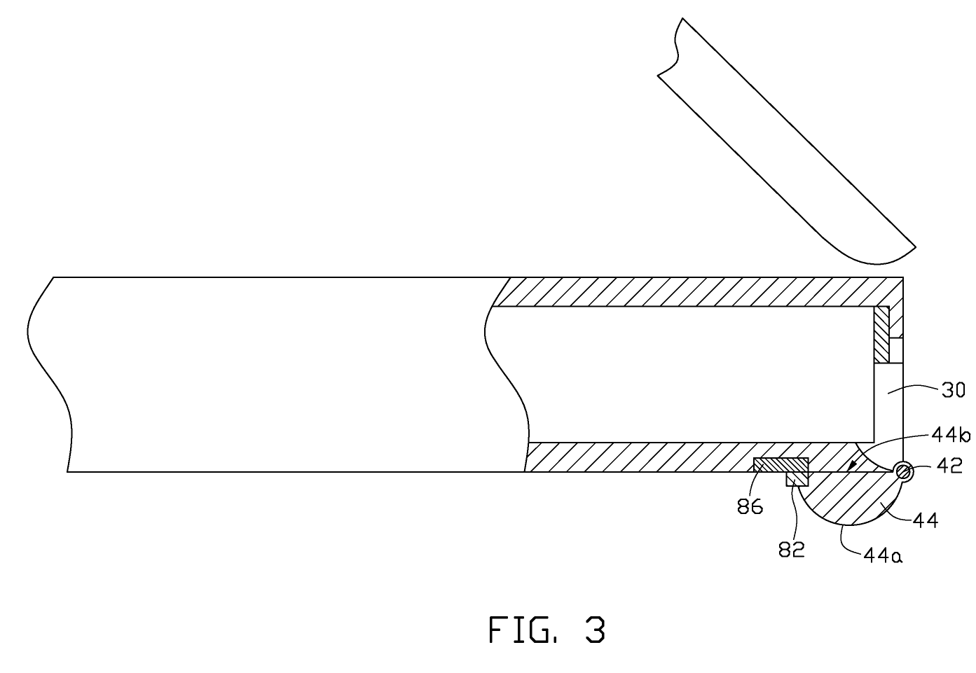

If the support leg 44 is positioned at the first position (see FIG. 2), the first securing member 82 matches with the second securing member 84 to keep the support leg 44 fix in the receiving portion 30. If the support leg 44 is positioned at the second position (see FIG. 3), the first securing member 82 matches with the third securing member 86 to keep the support leg 44 securely connected to the bottom surface 28 of the base 20.

The first securing member 82 is made from magnetic material, the second and third securing members 84, 86 are made from a material selected from the group consisting of iron, cobalt, magnet and nickel. Alternatively, the second and third securing members 84, 86 may be made from magnetic material and the first securing member 82 is made from a material selected from the group consisting of iron, cobalt, magnet and nickel. Referring to FIG. 2, the first securing member 82 is attracted to the second securing member 84, thereby the support leg 44 is held firmly in the receiving portion 30. Referring to FIG. 3, the first securing member 82 is pulled out of the receiving portion 30 and rotated around the hinge member 42 until magnetically connected to the third securing member 86, thereby the support leg 44 is held firmly to the bottom surface 28 of the base 20 for supporting the base 20.

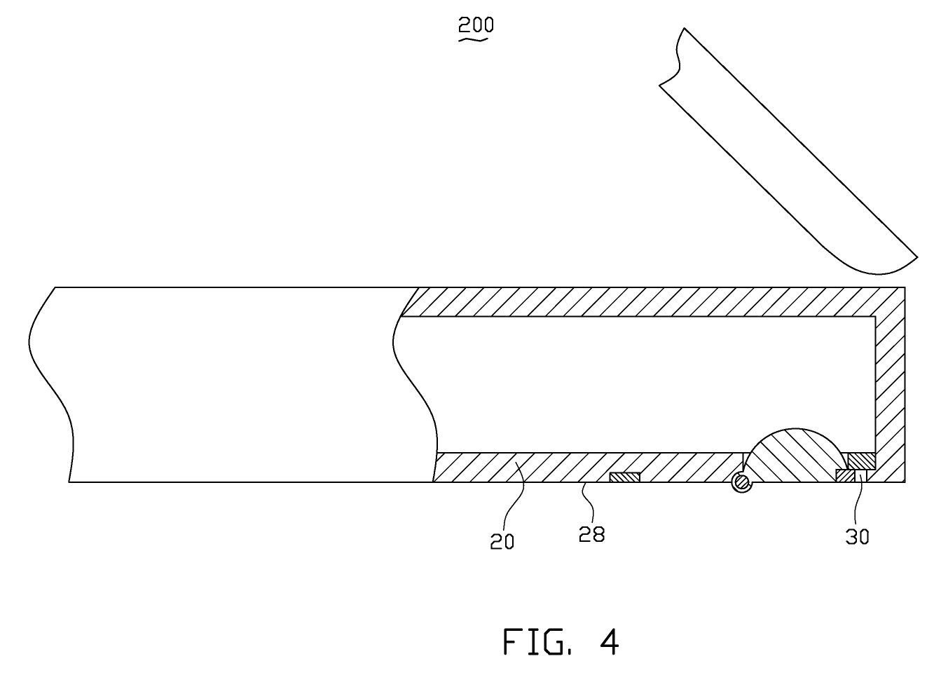

FIG. 4 is a cross-sectional view of a portable computer 200 according to a second embodiment. The portable computer 200 is similar to the portable computer 100 except that the receiving portion 30 is defined on the bottom surface 28 of the base 20.

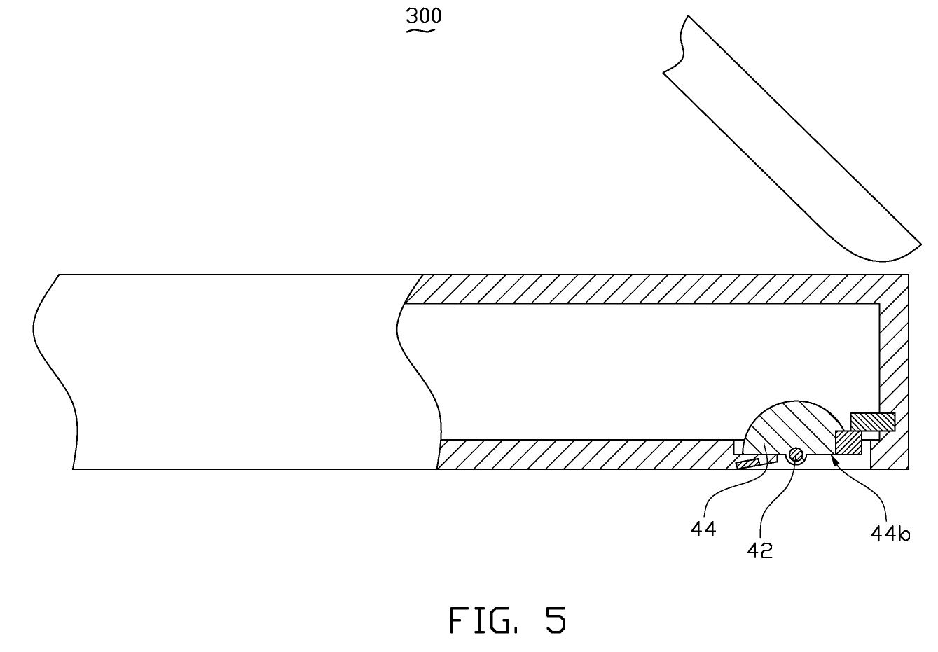

FIG. 5 is a cross-sectional view of a portable computer 300 according to a third embodiment. The portable computer 300 is similar to the portable computer 200 except that the hinge member 42 is disposed on the middle portion of the base surface 44b of the support leg 44.

Prior to use of the portable computers 100, 200 and 300, the support leg 44 can be pulled out of the receiving portion 30 to support the base 20, to allow a large air space forming between a support surface and the base of the portable computer and the air circulating therein freely, thereby cooling the portable computers. The support leg 44 can protect the portable computers from damage, because heat generated by the portable computers after extended usage can be dissipated, thus the use-life of the portable computers can be prolonged. When the portable computers 100, 200 and 300 are not in use, the support leg 44 can be retracted in the receiving portion 30. The portable computers 100, 200 and 300 having the support leg 44 are convenient to users.

It is to be understood, however, that even though numerous characteristics and advantages of the embodiments have been set forth in the foregoing description, together with details of the structures and functions of the embodiments, the disclosure is illustrative only, and changes may be made in detail, especially in matters of arrangement of parts within the principles of the invention to the full extent indicated by the broad general meaning of the terms in which the appended claims are expressed.

What is claimed is:

1. A portable computer comprising:
a base defining a receiving portion; and
a supporting member comprising a hinge member and a support leg, the supporting member pivotally coupled to the base via the hinge; the support leg being capable of rotating around the hinge member from a first position to a second position, the support leg being received in the receiving portion when the support leg is positioned at the first position, the support leg being configured for supporting the base when the support leg is positioned at the second position.

2. The portable computer as claimed in claim 1, wherein the base comprises a rear surface, a front surface opposite to the rear surface, two side surfaces and a bottom surface, the front surface, the rear surface and the side surfaces are connected to the bottom surface.

3. The portable computer as claimed in claim 2, wherein the receiving portion is defined on the rear surface of the base.

4. The portable computer as claimed in claim 2, wherein the receiving portion is defined on the front surface of the base.

5. The portable computer as claimed in claim 2, wherein the receiving portion is defined on the side surface of the base.

6. The portable computer as claimed in claim 2, wherein the receiving portion is defined on the bottom surface of the base.

7. The portable computer as claimed in claim 1, wherein the support leg is shaped as one of hemispherical, cubical and rectangular.

8. The portable computer as claimed in claim 7, wherein the support leg is hemispherical and comprises a base surface, the hinge member is disposed on the middle portion of the base surface of the support leg.

9. The portable computer as claimed in claim 2, further comprising a first securing member mounted on the support leg and a second securing member mounted on the receiving portion, the first securing member capable of matching with the second securing member when the support leg positioned at the first position.

10. The portable computer as claimed in claim 9, further comprising a third securing member mounted on the bottom surface of the base, the first securing member capable of matching with the third securing member when the support leg positioned at the second position.

11. The portable computer as claimed in claim 10, wherein the first securing member is made from magnetic material, the second and third securing members are made from a material selected from the group consisting of iron, cobalt, magnet and nickel.

12. The portable computer as claimed in claim 10, wherein the second and third securing members are made from magnetic material, the first securing member is made from a material selected from the group consisting of iron, cobalt, magnet and nickel.

13. The portable computer as claimed in claim 10, wherein the first, second and third securing members are made from magnetic material.

14. A portable computer comprising:
a base defining a receiving portion; and
a supporting member received in the receiving portion and pivotally connected with the base, the supporting member being configured for supporting the base when being pulled out of the receiving portion.

15. The portable computer as claimed in claim 14, wherein the base comprises a rear surface, a front surface opposite to the rear surface, two side surfaces and a bottom surface, the front surface, the rear surface and the side surfaces are connected to the bottom surface.

16. The portable computer as claimed in claim 15, wherein the receiving portion is defined on the rear surface of the base.

17. The portable computer as claimed in claim 15, wherein the receiving portion is defined on the front surface of the base.

18. The portable computer as claimed in claim 15, wherein the receiving portion is defined on the side surface of the base.

19. The portable computer as claimed in claim 15, wherein the receiving portion is defined on the bottom surface of the base.
